(19) United States
(12) Patent Application Publication
(10) Pub. No.: US 2013/0096866 A1
(43) Pub. Date: Apr. 18, 2013

(54) Method And Apparatus For Designing A Custom Test System

(71) Applicant: FORMFACTOR, INC., Livermore, CA (US)

(72) Inventor: Todd R. Kemmerling, Livermore, CA (US)

(73) Assignee: FORMFACTOR, INC., Livermore, CA (US)

(21) Appl. No.: 13/693,338

(22) Filed: Dec. 4, 2012

Related U.S. Application Data
(62) Division of application No. 12/044,600, filed on Mar. 7, 2008.

(51) Int. Cl. G01R 31/3183

(52) U.S. Cl. CPC G01R 31/318307
USPC 702/119

(57) ABSTRACT

Methods, apparatus, and computer readable media for designing a custom test system are described. Examples of the invention can relate to a method of generating test system software for a semiconductor test system. In some examples, a method can include obtaining a configuration of the semiconductor test system, the configuration including a description of a device under test (DUT) and a description of test hardware; and generating an application programming interface (API) specific to the configuration of the semiconductor test system, the API being generated based on the description of the DUT and the description of the test hardware, the API providing a programming interface between the test system software and the test hardware to facilitate testing of the DUT.

### BACKGROUND OF THE INVENTION

1. Field of the Invention

The present invention generally relates to semiconductor testing.

2. Description of the Related Art

Testing is an important step in the production of semiconductor devices. Typically, partially or fully completed semiconductor devices may be tested by bringing terminals disposed on an upper surface of a device to be tested—also referred to as a device under test (or DUT)—into contact with resilient contact elements, for example, as contained in a probe card assembly, as part of a semiconductor test system (“test system”). Test instruments may be coupled to the probe card assembly to send and receive test signals to and from the DUTs over a set of test channels. A test system controller, such as a computer system, may be coupled to the test instruments. The test system controller may execute test system software that can be used to control testing of the DUT.

A test system can be implemented to test a specific DUT. That is, a test system may include specific test instruments for testing a specific configuration of the DUT. As there are many types of DUTs, there are a myriad of potential configurations of a test system. Heretofore, test system software has been implemented to control several possible configurations of the test system. In other words, the test system software can include software for several possible configurations of the test system in a single package. This allows the same test system software to be used with various configurations of the test system. For a particularly configured test system, however, such test system software reduces system reliability by including extraneous software that will never be needed or used by the test system. Unneeded and unused software can add additional points of failure with no added benefit to a customer. Moreover, such test system software unnecessarily increases the footprint of the program code, thereby utilizing more memory resources than necessary.

Accordingly, there exists a need in the art for a method and apparatus for designing a custom test system that attempts to overcome at least some of the aforementioned deficiencies.

### SUMMARY OF THE INVENTION

Embodiments of the invention can relate to methods of generating test system software for a semiconductor test system. In some embodiments, a method can include obtaining a configuration of the semiconductor test system, the configuration including a description of a device under test (DUT) and a description of test hardware; and generating an application programming interface (API) specific to the configuration of the semiconductor test system, the API being generated based on the description of the DUT and the description of the test hardware, the API providing a programming interface between the test system software and the test hardware to facilitate testing of the DUT.

Embodiments of the invention can relate to apparatus for generating test system software for a semiconductor test system. In some embodiments, an apparatus can include means for obtaining a configuration of the semiconductor test system, the configuration including a description of a device under test (DUT) and a description of test hardware; and means for generating an application programming interface (API) specific to the configuration of the semiconductor test system, the API being generated based on the description of the DUT and the description of the test hardware, the API providing a programming interface between the test system software and the test hardware to facilitate testing of the DUT.

Embodiments of the invention can relate to semiconductor test systems. In some embodiments, a semiconductor test system can include test hardware configured to test a device under test (DUT); and a test system controller, coupled to the tester, configured to execute test system software, the test system software having an application programming interface (API) based on, and specific to, a description of the DUT and a description of the test hardware, the API providing a programming interface between the test system software and the test hardware to facilitate testing of the DUT.

Embodiments of the invention can relate to computer readable media having stored thereon instructions that, when executed by a processor, cause the processor to perform a method of generating test system software for a semiconductor test system. In some embodiments, the stored instructions can cause a processor to obtaining a configuration of the semiconductor test system, the configuration including a description of a device under test (DUT) and a description of test hardware; and generating an application programming interface (API) specific to the configuration of the semiconductor test system, the API being generated based on the description of the DUT and the description of the test hardware, the API providing a programming interface between the test system software and the test hardware to facilitate testing of the DUT.

### BRIEF DESCRIPTION OF THE DRAWINGS

So that the manner in which features of the various embodiments of the present invention can be understood in detail, a more particular description of the invention, briefly summarized above and described more fully below, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram depicting a semiconductor test system according to some embodiments of the invention;

FIG. 2 is a block diagram depicting the test system controller according to some embodiments of the invention;

FIG. 3 is a block diagram depicting the test system software according to some embodiments of the invention;

FIG. 4 is a block diagram depicting a system for generating test system software for a semiconductor test system according to embodiments of the invention; and

FIG. 5 is a flow diagram depicting a method of generating test system software for a semiconductor test system according to some embodiments of the invention.

Where possible, identical reference numerals are used herein to designate identical elements that are common to the figures. The images used in the drawings are simplified for illustrative purposes and are not necessarily depicted to scale.

### DETAILED DESCRIPTION

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on” and “attached to” are used herein, one object (e.g., a material, a layer, a substrate, etc.) can be “on” or “attached to” another object regardless of whether the one object is directly on or attached to the other object or there are one or more intervening objects between the one object and the other object. Also, directions (e.g., above, below, top, bottom, side, up, down, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

The present invention provides methods, apparatus, and computer readable media for designing a custom test system. In some embodiments, a configuration of a semiconductor test system can be obtained that includes a description of test hardware and a description of a device under test (DUT). A customized application programming interface (API) can be generated based on the descriptions that are specific to the configuration of semiconductor test system configuration. The API can provide a programming interface between test system software and test hardware to facilitate testing of the DUT. In some embodiments, the API can be used by components in the test system software that are nonspecific to the configuration of the semiconductor test system. Such components can use the API to interface with the test hardware and/or other components of the test system software. In this manner, the test system software as a whole is customized and specific to the configuration of the semiconductor test system and obviates the need to provide general purpose software capable of interfacing with an array of test system configurations. The customized test system software can exhibit a reduced code footprint, thereby utilizing less memory resources and being more efficient than larger, more general purpose software.

The present invention provides methods, apparatus, and computer readable media for managing test result data generated by a semiconductor test system. The test result data can be captured and processed for storage in a relational database. Thus, the test result data can be accessed and analyzed using any of various commercially available database management tools. The need for generating custom software to process and analyze test result data as output by the semiconductor test system can be avoided. By eliminating the need for such custom software, the cost of producing and operating the semiconductor test system may be reduced.

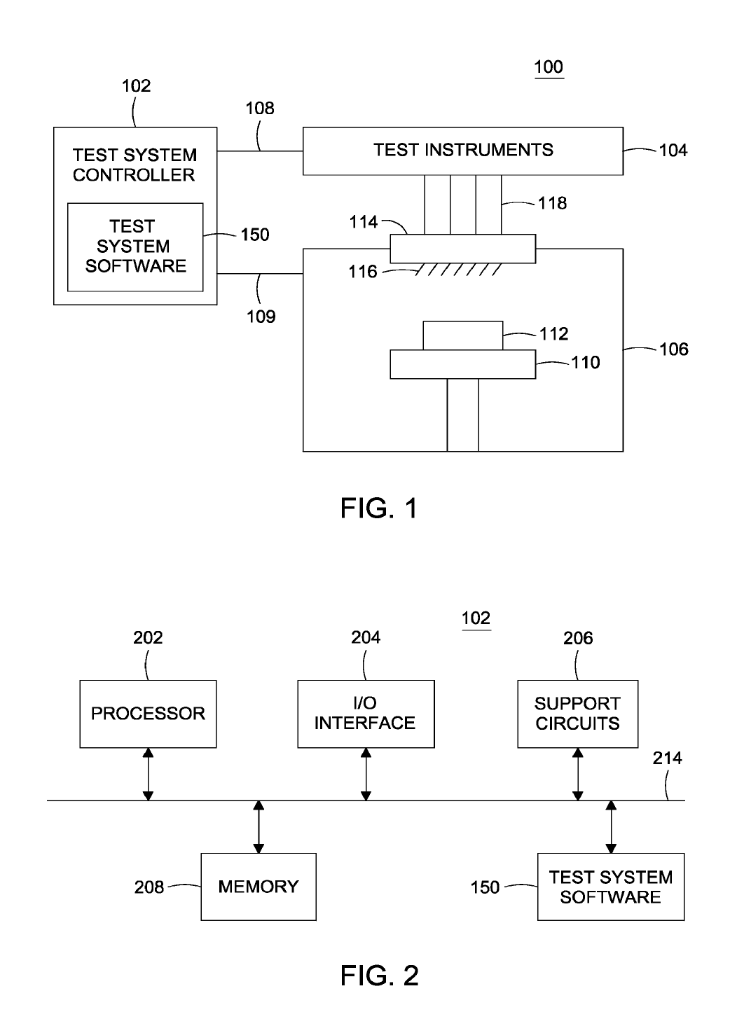

FIG. 1 is a block diagram depicting a semiconductor test system 100 according to some embodiments of the invention. The semiconductor test system 100 can generally include a test system controller 102, test instruments 104, a probe card assembly 114, and a prober 106. The test system controller 102 can be coupled to the test instruments 104 by a communication link 108. The test system controller 102 can be coupled to the prober 106 by a communication link 109. The prober 106 can include a stage 110 for mounting a device under test (DUT) 112 being tested. The DUT 112 can be any electronic device or devices to be tested. Non-limiting examples of a suitable DUT include one or more dies of an unsingulated semiconductor wafer, one or more semiconductor dies singulated from a wafer (packaged or unpackaged), an array of singulated semiconductor dies disposed in a carrier or other holding device, one or more multi-die electronics modules, one or more printed circuit boards, or any other type of electronic device or devices. The term DUT, as used herein, can refer to one or a plurality of such electronic devices.

The probe card assembly 114 can include probes 116 (also referred to as test probes) that contact the DUT 112. The stage 110 can be movable to contact the DUT 112 with probes 116. The test instruments 104 may be linked by connectors 118 to the probe card assembly 114. The links provided by the connectors 118 can be divided into individual test channels. The test channels may be used to convey test control signals or test signals (including test results). The connectors 118 may be any suitable connectors, such as flexible cable connectors, pogo pins, zero insertion force (ZIF) connectors, or the like. The probe card assembly 114 can fan out one or more of the test channels such that the signal conveyed therein can be coupled to multiple components.

The semiconductor test system 100 includes a particular configuration. The configuration may include a description of the DUT 112 and a description of test hardware. Test hardware, as used herein, can include the test instruments 104, the probe card assembly 114, and the prober 106. The DUT 112 can have particular specifications for which the test hardware is designed to test. For example, the DUT 112 may have a particular pin-out, specified electrical characteristics, and the like. The pin-out can includes various types and numbers of pins, such as, input/output (IO) pins, power pins, ground pins, and the like. The IO pins, for example, may be further classified depending on the function of the DUT 112. For example, if the DUT 112 comprises a memory device or memory devices, the IO pins may include address pins, data pins, control pins, and the like. The pins can be specified to receive and/or generate particular voltages and currents in accordance with the electrical specifications.

The test instruments 104 can include a particular specification of components for testing the DUT 112. A component, for example, may be a printed circuit board (PCB) having electronics for performing a particular function. For example, the test instruments 104 may include pin electronics for generating test signals for the DUT 112 and for receiving test result signals from the DUT 112, power supply electronics for generating power and ground for the DUT 112, and like type testing components known in the art. The probe card assembly 114 can include a particular specification of signal paths and probes 116 for supplying the test signals to, and receiving the test result signals from, the DUT 112, as well as various control signal paths (e.g., control signals for isolation switches on fanned out paths).

The test system controller 102 can include test system software 150 configured to control operation of the test hardware. The test system software 150 can control the generation of test signals by the test instruments 104, which can be transmitted through the probe card assembly 114, the probes 116, and ultimately to the DUT 112. The test system software 150 can control the reception of test result signals generated by the DUT 112 in response to the test signals. The test result signals can be provided from the DUT 112 back through the probe card assembly 114 to the test instruments 104 and ultimately to the test system controller 102. As described further below, the test system software 150 can include an application programming interface (API) that is specific to the test hardware and the DUT 112. The API can provide a customized programming interface between the test system software 150 and the test hardware to facilitate testing of the DUT 112, e.g., facilitate operation of the prober 106 and the test instruments 104. The API can be generated based on the configuration of the semiconductor test system 100 (e.g., descriptions of the test hardware and the DUT 112).

FIG. 2 is a block diagram depicting the test system controller 102 according to some embodiments of the invention. In addition to the test system software 150, the test system controller 102 may include a processor 202, an input/output (I/O) interface 204, support circuits 206, memory 208, each of which is coupled to a communication link 214 (e.g., communication bus(es) or the like). The processor 202 may include one or more microprocessors, microcontrollers, or the like known in the art. The support circuits 206 may include power supplies, clock circuits, data registers, and the like. The memory 208 may include random access memory, read only memory, optical read/write memory, magnetic read/write memory, or the like, as well as various combinations thereof. The I/O interface 204 may include any type of communication interface known in the art or combination of such communication interfaces for facilitating communication between the components in the test system controller 102 (e.g., the processor 202, the memory 208, the test system software 150), the test instruments 104, and the prober 106.

The test system software 150 may be stored in the memory 208 and/or on computer readable media, which may include information permanently stored on non-writable storage media (e.g., read-only memory devices within a computer such as CD-ROM or DVD-ROM disks readable by a CD-ROM drive or a DVD drive); alterable information stored on writable storage media (e.g., floppy disks within a diskette drive or hard-disk drive or read/writable CD or read/writable DVD); and the like. In some embodiments, one or more of the functions performed by the test system software 150 may be implemented using hardware, firmware, software, or some combination thereof. For example, all or a portion of the functions performed by the test system software 150 may be implemented using programmable logic devices (PLDs), application specific integrated circuits (ASICs), or the like.

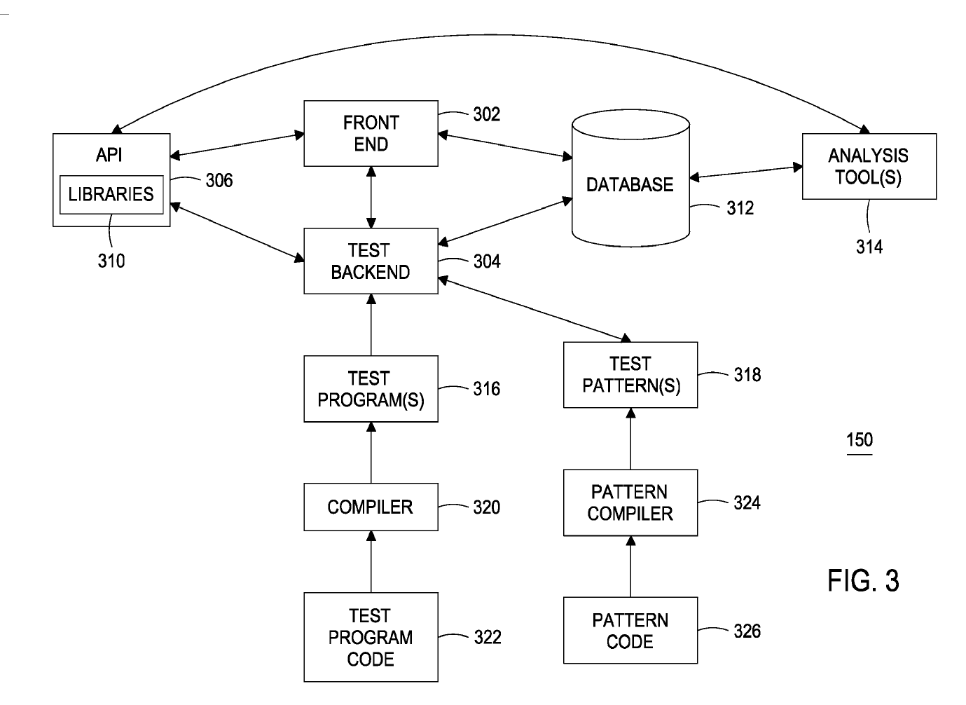

FIG. 3 is a block diagram depicting the test system software 150 according to some embodiments of the invention. The test system software 150 can include a front end 302, a test backend 304, an API 306, a database 312, and one or more analysis tools 314. The front end 302 can provide an interface to test system software 150 for receiving inputs and providing outputs to/from external entities. The front end 302 can be usable by a human operator and/or can provide an external interface to another system. In particular, the front end 302 can provide an interface to controlling the test backend 304.

The test backend 304 can be configured to control the test hardware (e.g., the test instruments 104 and the prober 106) in response to one or more test programs 316 and one or more test patterns 318. The test pattern(s) 318 can include a representation of test stimuli to be applied to the DUT 112. The test pattern(s) 318 can include a binary representation generated by a pattern compiler 324 from human readable pattern code 326. The test program(s) 316 can include instructions for controlling the sequence of test stimuli applied to the DUT 112. The test program(s) 316 can include a binary representation generated by a compiler 320 from human readable test program code 322. In some embodiments, the test system software 150 may include the compiler 320 and the pattern compiler 324 as part of a test development environment. In some embodiments, the compiler 320 and the pattern compiler 324 are omitted from the test system software 150, and the test program(s) 316 and the test pattern(s) 318 are provided as external input (i.e., the test development environment can be included in another external system). The test backend 304 can execute the test program(s) 316 under control of the front end 302.

The database 312 can store various data related to testing of the DUT 112. For example, the database 312 can store: an actual inventory of the test hardware installed in the semiconductor test system 100 (e.g., the specific test instruments, probe card assemblies, etc); an expected and/or required inventory of the installed test hardware for testing the DUT 112; an inventory of the test program(s) 316; specifications of the DUT 112 (e.g., pin-out, electrical characteristics, etc.); test result data obtained from the DUT 112 responsive to the testing (e.g., datalog information); system state information (e.g., DUT 112 currently under test), or like type data, as well as any combination of such data. The database 312 can be a relational database, such as a structured query language (SQL) database or like type relational database known in the art. The front end 302 and/or the test backend 304 can communicate with the database 312 to obtain data for controlling and executing the test program(s) 316.

The analysis tool(s) 314 can include various tools, such as a map tool for providing a visual representation of the DUT 112, one or more test result analysis tools for displaying various representations of the test result data, and like type tools known in the art. The analysis tool(s) 314 can communicate with the database 312 to obtain data for analysis.

The front end 302, the test backend 304, and the analysis tool(s) 314 can comprise executable modules. The test program(s) 316 can comprise a library or libraries that include routines for execution by the test backend 304. The API 306 can comprise libraries 310 that include routines for execution by the front end 302, the test backend 304, and the analysis tools 314. Those skilled in the art will appreciate that the test system software 150 can include other types of executable modules in addition to the front end 302, the test backend 304, and the analysis tool(s) 314. In addition, although separate modules are shown for the front end 302, the test backend 304, and the analysis tools 314, those skilled in the art will appreciate that the functionalities of one or more of these modules can be combined into one or more combined modules.

The front end 302, the test backend 304, and the analysis tool(s) 314 can call routines in the API 306. The API 306 can include one or more libraries 310 of routines. The API 306 can provide a customized programming interface between at least one component of the test system software 150 and the test hardware. The API can be specific to the configuration of the semiconductor test system 100 (e.g., specific to the test hardware and the DUT 112). As described below, the API 306 can be generated based on descriptions of the test hardware and the DUT. The API 306 can allow the front end 302, the test backend 304, and the analysis tool(s) 314 to be generic and nonspecific to the configuration of the semiconductor test system 100. Thus, the front end 302, the test backend 304, and the analysis tool(s) 314 can be used for an array of test system and DUT configurations. The API 306 can define a common set of routines that are callable by the front end 302, the test backend 304, and the analysis tool(s) 314. The implementation of these routines in the API 306 can be customized for the specific configuration of the semiconductor test system 100. Those skilled in the art will appreciate that the API 306 can be used by other executable modules in the test system software 150 in addition to the front end 302, the test backend 304, and the analysis tool(s) 314. These additional executable modules may also be nonspecific with respect to the configuration of the semiconductor test system 100.

In some embodiments, the libraries 310 can include a set of routines to perform command and status functions (“command and status library”). The command and status library can be used by executable modules, such as the front end 302, to communicate with the test backend 304. Exemplary routines in the command and status library can include a load routine for causing the test backend 304 to load a test program, a reset routine for causing the test backend 304 to return to its initial state, a test routine to cause the execution of a test, one or more status routines to obtain system status, and like type routines for controlling the test process.

In some embodiments, the libraries 310 can include a set of routines for interfacing hardware in the test system 100 (“hardware library”). The hardware library can be used by executable modules, such as the test backend 304, to control the test hardware. Exemplary routines in the hardware library can include routines for interfacing with the test instruments 104, routines for interfacing with the prober 106, routines for interfacing with the probe card assembly 114, and the like.

In some embodiments, the libraries 310 can include a set of routines for interfacing the database 312 (“database library”). The database library may include routines that can be used by the executable modules, such as the front end 302, the test backend 304, and the analysis tool(s) 314, to perform database activities, such as storing data, querying data, retrieving data, creating database schemas, and the like. Exemplary routines in the database library can include routines for obtaining an inventory of the test hardware, routines for obtaining an inventory of test programs, routines for storing and obtaining test result data, routines for updating and obtaining system state information, and the like.

Those skilled in the art will appreciate that the command and status library, the hardware library, and the database library may include a myriad of other types of routines to facilitate testing of the DUT 112. Moreover, the libraries 310 can include other types of libraries in addition to those described above, such as a library for handling errors (exceptions), a library having routines for use by the test program(s) 316, and the like. In general, all or a portion of one or more of the libraries 310 can be specific to the configuration of the semiconductor test system 100 (e.g., specific to the test instruments 104 and the DUT 112).

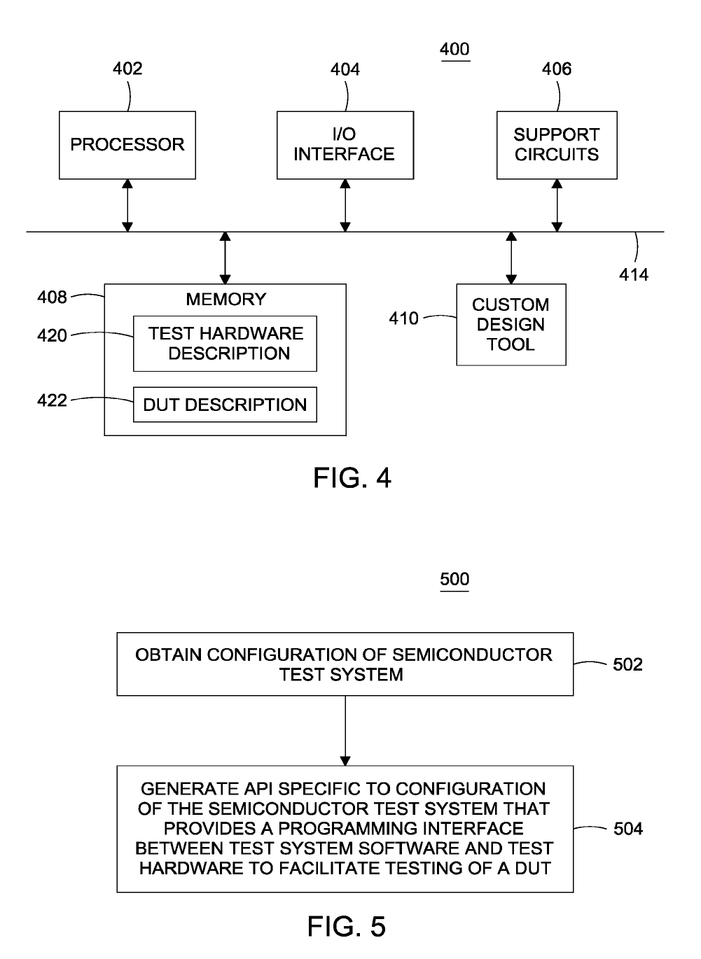

FIG. 4 is a block diagram depicting a system 400 for generating test system software for a semiconductor test system according to embodiments of the invention. The system 400 may include a processor 402, an input/output (I/O) interface 404, support circuits 406, memory 408, and a custom design tool 410, each of which is coupled to a communication link 414 (e.g., communication bus(es) or the like). The processor 402 may include one or more microprocessors, microcontrollers, or the like known in the art. The support circuits 406 may include power supplies, clock circuits, data registers, and the like. The memory 408 may include random access memory, read only memory, optical read/write memory, magnetic read/write memory, or the like, as well as various combinations thereof. The I/O interface 404 may include any type of communication interface known in the art or combination of such communication interfaces for facilitating communication between the components in the system 400 (e.g., the processor 402, the memory 408, and the custom design tool 410).

The custom design tool 410 can be used to generate all or a portion of the test system software 150. The custom design tool 410 can obtain a description 420 of the test hardware and a description 422 of the DUT 112. The descriptions 420 and 422 may be stored in the memory 408. The description 422 of the DUT 112 can include a particular pin-out of the DUT 112, specified electrical characteristics of the DUT 112, or like type information describing the DUT 112. The description 420 of the test hardware can include a particular configuration of components, such as the number and types of the test instruments 104, the number and types of probe card assemblies, and the like. Based on the descriptions 420 and 422, the custom design tool 410 can generate the API 306 of the test system software 150. For example, the API 306 may include a common set of routines used by the nonspecific portions of the test system software 150 (e.g., the front end 302, the test backend 304, the analysis tool(s) 314). A base implementation may be defined for each of the routines having placeholders for specific implementation details. Given the descriptions 420 and 422, the custom design tool 410 can replace the placeholders with the corresponding specific implementations. In this manner, the API 306 can become specific to the test hardware and the DUT 112.

Other portions of the test system software 150 can be nonspecific to the configuration of the semiconductor test system 100, as described above. Thus, the custom design tool 410 can generate such portions irrespective of the descriptions 420 and 422 (e.g., the front end 302, the test backend 304, and the analysis tool(s) 314).

The term “nonspecific”, as used herein, indicates that tools do not depend on the specific configuration of the test system. Such nonspecific tools can be used with multiple test systems having different configurations. As described above, examples of nonspecific tools include the front end 302, the test backend 304, and the analysis tool(s) 314. Such tools can be nonspecific because of the customized API 306. The term “specific”, as used herein, indicates that API routines depend on the specific configuration of the test system (e.g., configuration of test instruments, configuration of DUT, etc.). The specific API routines can be generated for each different configuration of a test system. For example, specific routines in the API 306 provide an interface between the nonspecific tools in the test system software 150 and the specifically configured test system.

In some embodiments, the custom design tool 410 can include software having instructions executable by the processor 402. The software may be stored in the memory 408 and/or on computer readable media, which may include information permanently stored on non-writable storage media (e.g., read-only memory devices within a computer such as CD-ROM or DVD-ROM disks readable by a CD-ROM drive or a DVD drive); alterable information stored on writable storage media (e.g., floppy disks within a diskette drive or hard-disk drive or read/writable CD or read/writable DVD); and the like. In other embodiments, the custom design tool 410 may comprise hardware, firmware, software, or some combination thereof. For example, all or a portion of the custom design tool 410 may be implemented using programmable logic devices (PLDs), application specific integrated circuits (ASICs), or the like.

FIG. 5 is a flow diagram depicting a method 500 of generating test system software for a semiconductor test system according to some embodiments of the invention. A configuration of the semiconductor test system can be obtained (502). The configuration can include a description of the DUT and a description of test hardware. The test hardware can include a plurality of test instruments configured for communication with the DUT through a probe card assembly by a prober. An API can be generated specific to the configuration of the semiconductor test system (504). The API can be based on the description of the test hardware and the description of the DUT. The API can provide a programming interface between the test system software and the test hardware to facilitate testing of the DUT. In some embodiments, the test system software includes at least one component nonspecific to the configuration of the semiconductor test system. Each of the components can call routines defined by the API in order to interface with the test hardware or with other components in the test system software.

While the foregoing is directed to embodiments of the present invention, other and further embodiments of the invention may be devised without departing from the basic scope thereof, and the scope thereof is determined by the claims that follow.

1-7. (canceled)

8. An apparatus for generating test system software for a semiconductor test system, comprising:
means for obtaining a configuration of the semiconductor test system, the configuration including a description of a device under test (DUT) and a description of test hardware; and
means for generating an application programming interface (API) specific to the configuration of the semiconductor test system, the API being generated based on the description of the DUT and the description of the test hardware, the API providing a programming interface between the test system software and the test hardware to facilitate testing of the DUT.

9-40. (canceled)
